(19) United States
(12) Patent Application Publication
(10) Pub. No.: US 2008/0095277 A1
(43) Pub. Date: Apr. 24, 2008

(54) Transmission and detection of preamble signal in OFDM communication system

(76) Inventor: Lixin Cheng, San Diego, CA (US)

Correspondence Address: Lixin Cheng, 11985 Heatherwood Hollow CT., San Diego, CA, 92128, US

(21) Appl. No.: 11/974,314

(22) Filed: Oct. 12, 2007

Related U.S. Application Data
(60) Provisional application No. 60/852,955, filed on Oct. 19, 2006.

(51) Int. Cl. H03D 1/00; H04L 27/06

(52) U.S. Cl. 375/340

(57) ABSTRACT

A wireless communication method using wireless signals including a preamble, the method comprising: acquiring a first symbol of the preamble by searching a common waveform; progressively acquiring subsequent symbols of the preamble using information from previous symbols including the first symbol; and acquiring critical system configuration information embedded in the preamble using the first symbol and the subsequent symbols.

### RELATED APPLICATION

This application claims the benefit of priority of co-pending U.S. Provisional Patent Application Ser. No. 60/852,955, filed Oct. 19, 2006, and entitled “Method and Apparatus of Transmission and Detection of a Preamble signal in an OFDM Communication System.” The disclosure of the above-referenced patent application is hereby incorporated by reference.

### BACKGROUND

1. Field of the Invention

The present invention relates generally to preambles for wireless communication systems such as orthogonal frequency-division multiplexing (OFDM) and, more particularly, to handling critical system parameters in the preambles.

2. Related Art

Orthogonal frequency-division multiplexing (OFDM) is an advanced technique to transmit high-bit-rate data over wireless communication systems. Effective preamble design is an important part for an OFDM technology commercialization since the preamble design is directly related to the system capacity, the acquisition efficiency, and the battery life.

In conventional OFDM systems with flexible configuration parameters, preamble is usually complicated and has too much overhead. Thus, the acquisition complexity is often prohibitive, and the terminal acquisition process becomes lengthy. Further, the battery power consumption at a mobile terminal becomes critical.

### SUMMARY

Embodiments of the present invention include systems and methods to implement techniques for wireless communication.

In one aspect, a wireless communication method using wireless signals including a preamble is disclosed. The method comprising: acquiring a first symbol of the preamble by searching a common waveform; progressively acquiring subsequent symbols of the preamble using information from previous symbols including the first symbol; and acquiring critical system configuration information embedded in the preamble using the first symbol and the subsequent symbols.

In another aspect, a wireless communication method for modulating system parameters onto orthogonal sub-carriers of a preamble OFDM symbol is disclosed. The method comprises: encoding and modulating the system parameters onto modulation symbols; mapping the modulation symbols to substantially all orthogonal sub-carriers including guard sub-carriers; discarding the guard sub-carriers; and transmitting the orthogonal sub-carriers.

Other features and advantages of the present invention will become more readily apparent to those of ordinary skill in the art after reviewing the following detailed description and accompanying drawings.

### BRIEF DESCRIPTION OF THE DRAWINGS

The details of the present invention, both as to its structure and operation, may be understood in part by studying the accompanying drawings, in which like reference numerals refer to like parts, and in which:

FIG. 1A shows an example structure of a preamble for a wireless communication system in accordance with one embodiment of the present invention;

FIG. 1B shows another example of a preamble structure in accordance with an alternative embodiment of the present invention;

FIG. 2 is a flowchart of a conventional method for encoding and modulating a system parameter packet onto OFDM symbol sub-carriers;

FIG. 3 graphically depicts the conventional modulation method shown in FIG. 2;

FIG. 4 is a flowchart of a method for encoding and modulating system parameter packets onto OFDM symbol sub-carriers in accordance with one embodiment of the present invention; and

FIG. 5 graphically depicts the modulation method shown in FIG. 4.

### DETAILED DESCRIPTION

As will be further described below, embodiments of the present invention provide the need for wireless communication systems with flexible configuration parameters and efficient system acquisitions by progressively acquiring critical system configuration information (e.g., system parameter packets) embedded in the preamble. Accordingly, the embodiments enable the system parameter packets for a wireless communication system to be decoded faster and more efficiently than the conventional wireless communication system. Further, the embodiments of the present invention can be adapted for use in other advanced wireless technologies in which optimization of the balance of system capacity and terminal acquisition speed is desirable.

After reading this description it will become apparent to one skilled in the art how to implement the invention in various embodiments and applications. However, although various embodiments of the present invention will be described herein, it is understood that these embodiments are presented by way of example only, and not limitation. As such, this detailed description of various embodiments should not be construed to limit the scope or breadth of the present invention as set forth in the appended claims.

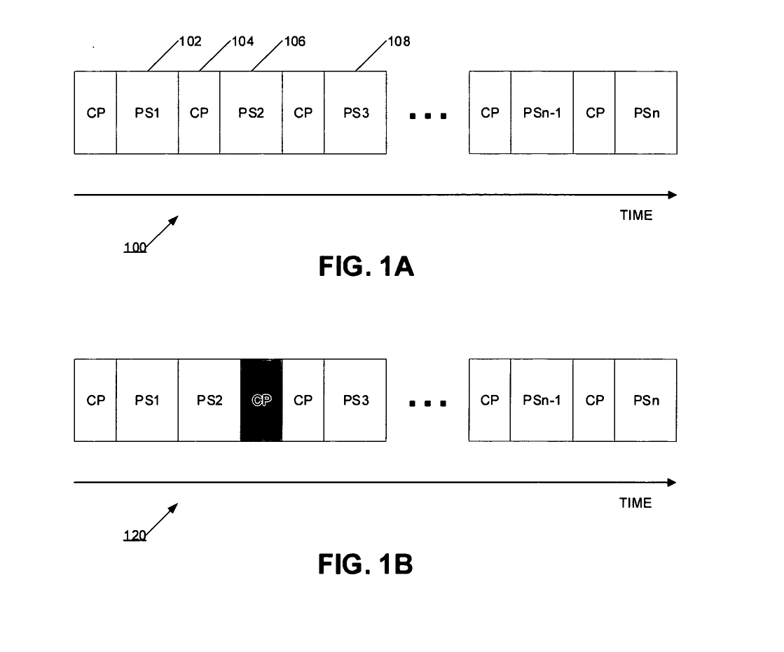

FIG. 1A shows an example structure of a preamble 100 for a wireless communication system in accordance with one embodiment of the present invention. The preamble 100 includes preamble symbols (PSx), where each preamble symbol is preceded by a cyclic prefix (CP). Each preamble symbol can also be preceded or succeeded by system parameter packets (not shown in FIG. 1A or 1B). A system parameter packet is a packet that includes a group of system configuration parameters such as a number of guard sub-carriers, system FFT size, and other deployment related parameters.

The preamble is generated in a transmitter as a predetermined series of preamble symbols (PSx) in such a way that the information required for acquiring the next preamble symbol as well as preceding symbols is embedded in the current preamble. For example, as illustrated in FIG. 1A, the information required to acquire PS2 (106) in the preamble is embedded in PS1 (102). Moreover, the information required to acquire PS3 (108) is embedded in PS2 (as well as in PS1), and so on. The total number of required preamble symbols is dependent on the number of configurable system parameters.

The embedding of information in preamble symbols can be done by modulating (or scrambling) the preamble symbols, either in time or frequency domain, with a sequence, such as the well-known PN sequence, or other known types of sequences. This results in a distinct time waveform or frequency spectrum. A distinct sequence represents specific information about the system. The required number of distinct sequences depends on the amount of information the preamble symbol carries. For example, if a preamble symbol contains the information (i.e., the length) of the cyclic prefix of an OFDM symbol, the number of sequences required to represent the lengths of the cyclic prefix depends on the allowed number of different lengths of the cyclic prefix.

In an access terminal, the first preamble symbol (PS1) 102 is initially searched, and the position of PS1 is used as timing information for PS2. In one embodiment, PS1 may include other information required to acquire PS2 in addition to the position information. For example, the information (length) of CP 104 can be embedded in PS1 to provide complete information needed to acquire PS2 (106) since the actual position of PS2 also depends on the CP length. Once PS2 is acquired, the information embedded in PS2 is used to acquire PS3. PS2 may also include “signature” information about a system to which the access terminal desires to gain access. Thus, the “signature” information may include a seed to the PN sequence used to identify a sector/cell in a cellular communication system.

PS3, as well as the signals after PS3, is scrambled by the sector/cell specific PN sequence. The PN sequence information (seed) acquired from PS2, along with the CP information from PS1, can then be used to acquire PS3. PS3 may include information such as synchronous/asynchronous mode, system time information, hopping pattern (if preamble hopping is used), and other related information. In some cases, system information may include only a portion of the system time (e.g., a few least significant bits) if the processing of the subsequent signal requires system time information. This procedure continues until PSn is acquired. At this time, the access terminal has the least information needed to decode the first system parameter packet.

In another embodiment of the preamble 120 shown in FIG. 1B, PS1 includes a common waveform (known to access terminals) to all systems (i.e., communication systems that provide services to access terminals). This common waveform reduces the complexity of acquisition in an access terminal since only one waveform needs to be detected. This is in contrast to the first embodiment (shown in FIG. 1A) where multiple waveforms needs to be tested during acquisition of PS1. The information (length) of CP is embedded in PS2 together with other critical information such as the sector/cell signature information (or portion of the signature) for cellular systems. Since the access terminal does not know the CP length after the detection of PS1, there may be ambiguity regarding the actual position of PS2. However, the waveform of PS2 and CP can be manipulated in such a way that the PS2 starts right after PS1. The “CP” is relocated to another position in the preamble 120. In some cases, the CP of PS2 can even be removed. This enables the access terminal to locate PS2 without the knowledge of the CP length. Since the CP length is determined after the acquisition of PS2, PS3 can then be located. Once the last PS is acquired, the access terminal should have the information needed to decode the first system parameter packet.

To summarize, the above description discloses the wireless communication method using wireless signals including a preamble. The method includes acquiring a first symbol of the preamble by searching a common waveform; progressively acquiring subsequent symbols of the preamble using information from previous symbols including the first symbol; and acquiring critical system configuration information embedded in the preamble using the first symbol and the subsequent symbols.

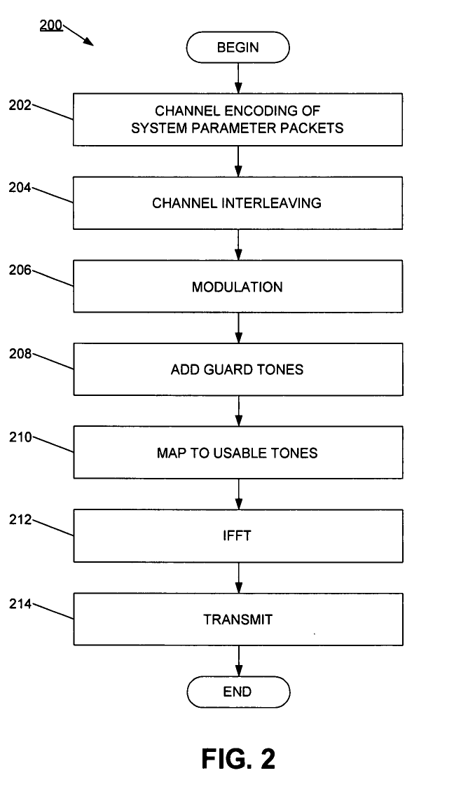

FIG. 2 is a flowchart of a conventional method 200 for modulating system parameter packets onto OFDM symbol sub-carriers. The system parameter packets are encoded, at 202, with a channel encoder, such as a convolutional encoder. The system parameter packets are channel interleaved, at 204, and modulated, at 206. Guard tones (e.g., 312, 314) are added, at 208, and modulation symbols (e.g., 302) are mapped, at 210, to usable OFDM sub-carriers or tones (e.g., 306). Inverse Fast Fourier Transform (IFFT) is performed on the modulation symbols, at 212, which are then prepared for transmission, at 214.

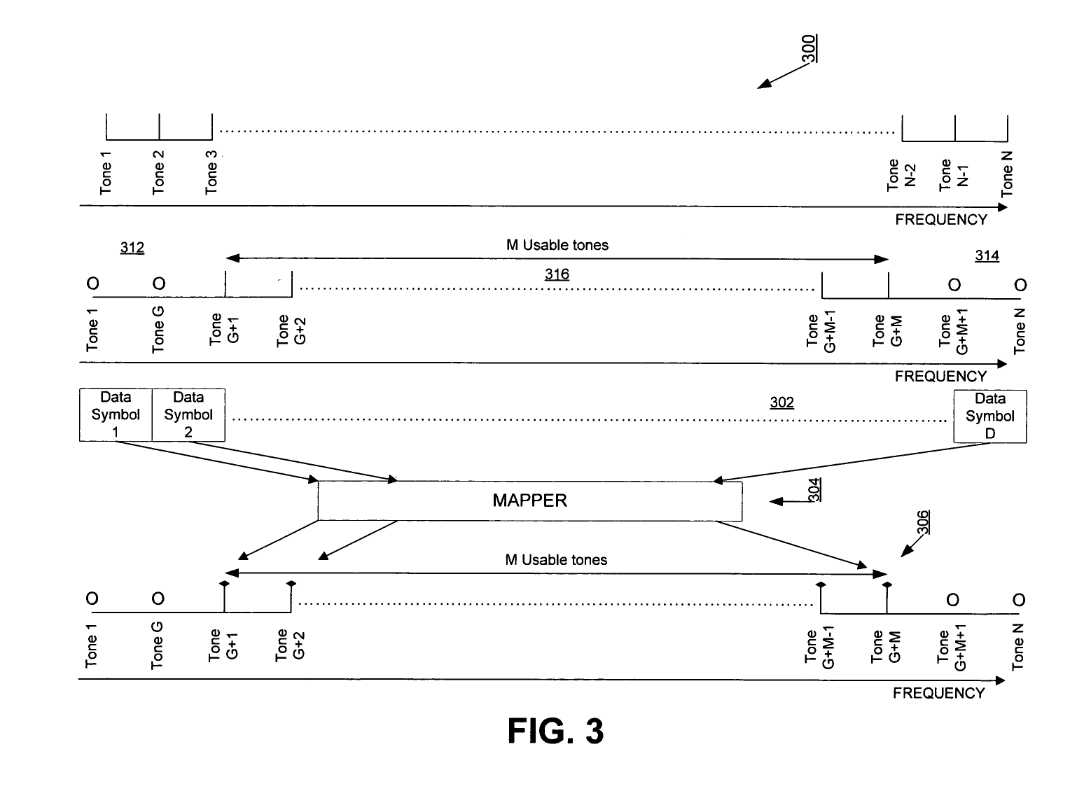

FIG. 3 graphically depicts the conventional modulation method 200 shown in FIG. 2. As described above, the system parameter packets are channel encoded, channel interleaved, and modulated. The guard tones 312, 314 are added and modulation symbols 302 are then mapped by a mapper 304 to usable OFDM sub-carriers or tones 306 for transmission.

Usable sub-carriers are sub-carriers that do not include guard sub-carriers 312, 314 (i.e., sub-carriers that cannot be used for carrying signals). Therefore, the modulation symbol to sub-carrier mapper 304 is a function that depends on the number of usable sub-carriers 316 or the number of guard sub-carriers 312, 314. Different number of usable sub-carriers/guard sub-carriers corresponds to different mapping. Accordingly, the access terminal must find out the exact number of usable sub-carriers or guard sub-carriers before de-mapping and decoding of the system parameter packet. This requires large preamble symbol overhead and acquisition complexity because of the wide variation of a number of guard sub-carriers for differently deployed systems.

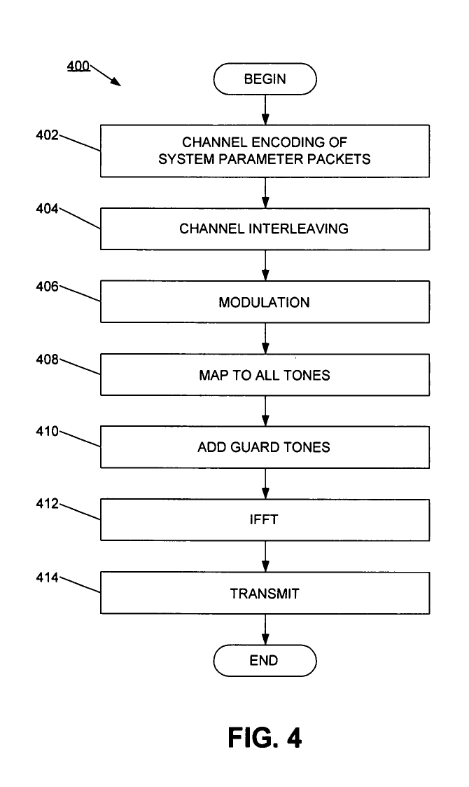

FIG. 4 is a flowchart of a method 400 for modulating system parameter packets onto OFDM symbol sub-carriers in accordance with one embodiment of the present invention. At 402, the system parameter packets are encoded with a channel encoder such as a convolutional encoder. The system parameter packets are channel interleaved, at 404, and modulated (e.g., with Quadrature Phase Shift Keying (QPSK)), at 406. Modulation symbols (e.g., 502) are then mapped, at 408, to all OFDM sub-carriers or tones (e.g., 506) for transmission.

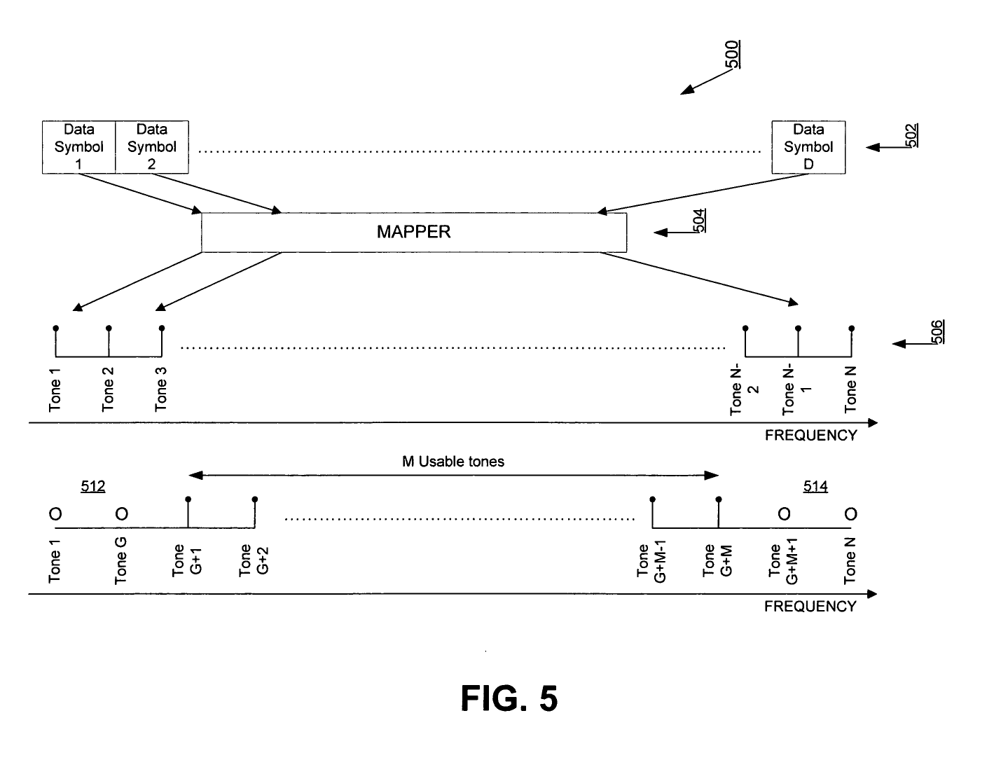

FIG. 5 graphically depicts the modulation method 400 shown in FIG. 4. In the illustrated embodiment of FIG. 5, the modulation symbols 502 are mapped to all OFDM sub-carriers or tones 506 by a sub-carrier mapper 504. However, in the illustrated embodiment, the mapping is made independent of the usable sub-carriers or guard tones but is made dependent on a total number of sub-carriers N (or FFT size N) of the preamble, which is designed to be common to all the deployments. That is, the mapping is fixed regardless of the actual size of the usable sub-carriers or bandwidth of the preamble.

Referring back to FIG. 4, the mapper 504 maps the modulation symbols 502 to sub-carriers 506, at 408, as if all sub-carriers 506 were usable. However, if a symbol (e.g., modulated at 406) is mapped to a non-usable tone or a guard sub-carrier, the modulation symbols is discarded or punctured and the sub-carrier is left unmodulated or unused (e.g., a zero energy state). Thus, equivalently, the guard sub-carriers 512, 514 are added or re-enforced, at 410, after the mapping (at 408). Inverse Fast Fourier Transform (IFFT) is performed on the modulation symbols, at 412, which are then prepared for transmission, at 414.

It should be noted that the separation of steps 408 and 410 is only for illustration purpose. Accordingly, in the illustrated embodiment, the modulation symbols of the system parameter packet are de-mappable (i.e., decodable) even without the exact knowledge of preamble bandwidth information. Hence, preamble symbols do not need to carry information (e.g., size) of guard sub-carriers. This feature makes it possible for the receiver to decode system parameters without the exact knowledge of the number of guard tones. For example, the receiver may conservatively decode the system parameters by only using the minimum usable tones. It is possible to include coarse information of the guard sub-carrier in PS to aid in decoding the system parameter packet without causing too much overhead. The first system parameter packet includes almost all of the information that is necessary but lacking in the preamble symbols needed to decode the second system parameter packet. The information includes the total number of system sub-carriers (system FFT size) if the system FFT size can be different from the preamble FFT size, the number of guard sub-carriers, and other related parameters.

After successful decoding of the first system parameter packet, the information obtained from the decoding is used to decode the second system parameter packet, and so on. Thus, the system parameter packets include all information needed to access the system.

The waveform used by PS1 is typically a periodic waveform with p periods. In one embodiment, the receiver may search with a conservative bandwidth, such as the minimum bandwidth, which is typically predetermined and common to all systems. In other embodiments, more aggressive search bandwidth may be used. The receiver correlates the received signal at time t against one period of the waveform to produce a correlation signal.

The receiver uses the current correlation signal value together with the past p−1 values that are one period (N/p) apart to first estimate the phase difference among p values. The estimated phase difference is then used to remove the phase shift of the p values and summed. The amplitude of the sum is tested against a threshold and used as an indication of detection of the PS1. It is also possible to sum up the amplitude of the p values without removing the phase shift and use it as the PS1 detector. It is well known that the above-described correlation can be done more efficiently using FFT.

An alternative method is to calculate an autocorrelation of the correlation signal with distance equal to the period of the PS1 waveform. The autocorrelation is then thresholded to remove baseline noise and detected for rising and trailing edges which corresponds to the beginning and ending of the PS1 symbol.

The same procedure repeats at time t+Δt until the preamble is detected. The value of Δt is somewhat arbitrary (e.g., the value can be one sample or N/p samples).

In the illustrated embodiment, the mapping is made independent of the usable sub-carriers or guard tones but is made dependent on a total number of sub-carriers N (or FFT size N) of the preamble, which is designed to be common to all the deployments. That is, the mapping is fixed regardless of the actual size of the usable sub-carriers or bandwidth of the preamble.

Referring to FIG. 5 again, the mapper 504 maps the modulation symbols to sub-carriers as if all the sub-carriers 506 were usable. However, if a symbol (e.g., modulated at 406) is mapped to a non-usable tone or a guard sub-carrier, the modulation symbols is discarded or punctured and the sub-carrier is left unmodulated or unused (e.g., a zero energy state). Thus, equivalently, the guard sub-carriers are added or re-enforced (see 508) after mapping by the mapper 504.

One implementation includes one or more programmable processors and corresponding computer system components to store and execute computer instructions, such as to provide the various subsystems of a wireless communication system as described above.

The present invention is not limited to the above embodiments. As the present invention may be embodied in several forms without departing from the spirit or essential characteristics thereof, it should also be understood that the above-described examples are not limited by any of the details of the description, unless otherwise specified, but rather should be constructed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A wireless communication method using wireless signals including a preamble, the method comprising:
acquiring a first symbol of the preamble by searching a common waveform;
progressively acquiring subsequent symbols of the preamble using information from previous symbols including the first symbol; and
acquiring critical system configuration information embedded in the preamble using the first symbol and the subsequent symbols.

2. The wireless communication method of claim 1, wherein said progressively acquiring subsequent symbols includes
acquiring the subsequent symbols without knowledge of the length of a cyclic prefix.

3. The wireless communication method of claim 2, further comprising:
determining the length of the cyclic prefix after acquiring a second symbol; and
acquiring a third symbol.

4. A wireless communication method for modulating system parameters onto orthogonal sub-carriers of a preamble, the method comprising:
encoding and modulating the system parameters onto modulation symbols;
mapping the modulation symbols to substantially all orthogonal sub-carriers including guard sub-carriers;
discarding the guard sub-carriers; and
transmitting the orthogonal sub-carriers.

5. The wireless communication method of claim 4, wherein said mapping the modulation symbols to substantially all orthogonal sub-carriers includes
mapping the modulation symbols based on a total number of the orthogonal sub-carriers of the preamble.

6. The wireless communication method of claim 5, wherein said mapping the modulation symbols based on a total number of the orthogonal sub-carriers is done independent of the bandwidth of the preamble.

7. The wireless communication method of claim 4, wherein said mapping the modulation symbols to substantially all orthogonal sub-carriers enables receivers to decode system parameters by using a minimum number of usable sub-carriers.

8. The wireless communication method of claim 4, further comprising:
receiving the orthogonal sub-carriers; and
decoding a first parameter packet using the received orthogonal sub-carriers without knowledge of the number of guard sub-carriers.

9. The wireless communication method of claim 8, further comprising
decoding a second parameter packet using information obtained from said decoding of a first parameter packet.

10. A wireless communication apparatus comprising:
a) means for modulating system parameters onto orthogonal sub-carriers of a preamble comprising:
1) means for encoding and modulating the system parameters onto modulation symbols;
2) means for mapping the modulation symbols to substantially all orthogonal sub-carriers including guard sub-carriers, and to discard the guard sub-carriers; and
b) means for transmitting the orthogonal sub-carriers.

11. The wireless communication apparatus of claim 10, wherein said means for mapping maps the modulation symbols based on a total number of the orthogonal sub-carriers of the preamble.

12. The wireless communication apparatus of claim 11, wherein said second means for mapping is configured to be independent of the bandwidth of the preamble.

13. The wireless communication apparatus of claim 10, wherein said means for mapping enables receivers to decode system parameters by using a minimum number of usable sub-carriers.

14. The wireless communication apparatus of claim 10, further comprising:
mean for receiving the orthogonal sub-carriers; and
means for decoding a first parameter packet using the received orthogonal sub-carriers without knowledge of the number of guard sub-carriers.

15. The wireless communication apparatus of claim 14, further comprising
means for decoding a second parameter packet using information obtained from said means for decoding of a first parameter packet.
